(19) United States
(12) Patent Application Publication
(10) Pub. No.: US 2011/0258513 A1
(43) Pub. Date: Oct. 20, 2011

(54) SNR-Based Variable-Threshold Majority-Logic Decoder

(76) Inventors: Jing Qian, Allston, MA (US); Cao Zhigang, Beijing (CN); Baoguo Yang, San Jose, CA (US)

(21) Appl. No.: 12/991,484

(22) PCT Filed: May 8, 2009
(86) PCT No.: PCT/US09/43263

§ 371 Date: May 31, 2011

Related U.S. Application Data
(60) Provisional application No. 61/051,637, filed on May 8, 2008.

(51) Int. Cl. H03M 13/43; G06F 11/10

(52) U.S. Cl. 714/760; 714/E11.032

(57) ABSTRACT

Apparatus having corresponding methods and tangible computer-readable medium embodying instructions executable by a computer to perform the methods comprise: a receiver adapted to receive a signal representing an input code block, wherein the input code block represents information encoded with a (N, K) difference-set cyclic code, wherein the input code block includes N symbols, and wherein the N symbols represent K bits of the information; an estimator adapted to estimate a signal-to-noise ratio of the signal; a raised-threshold majority-logic decoder adapted to decode the input code block according to a raised-threshold majority-logic decoding algorithm when the signal-to-noise ratio does not exceed a first predetermined threshold; and a variable-threshold majority-logic decoder adapted to decode the input code block according to a variable-threshold majority-logic decoding algorithm when the signal-to-noise ratio exceeds the first predetermined threshold.

### CROSS-REFERENCE TO RELATED APPLICATIONS

This application claims benefit of U.S. Provisional Patent Application Ser. No. 61/051,637 filed May 8, 2008, the disclosure thereof incorporated by reference herein in its entirety.

### BACKGROUND

The present disclosure relates generally to decoding encoded data. More particularly, the present disclosure relates to decoding encoded data based on a signal-to-noise ratio of a signal representing the encoded data, where the data is encoded using a difference-set cyclic code.

### SUMMARY

In general, in one aspect, an embodiment features an apparatus comprising: a receiver adapted to receive a signal representing an input code block, wherein the input code block represents information encoded with a (N, K) difference-set cyclic code, wherein the input code block includes N symbols, and wherein the N symbols represent K bits of the information; an estimator adapted to estimate a signal-to-noise ratio of the signal; a raised-threshold majority-logic decoder adapted to decode the input code block according to a raised-threshold majority-logic decoding algorithm when the signal-to-noise ratio does not exceed a first predetermined threshold; and a variable-threshold majority-logic decoder adapted to decode the input code block according to a variable-threshold majority-logic decoding algorithm when the signal-to-noise ratio exceeds the first predetermined threshold.

Embodiments of the apparatus can include one or more of the following features. In some embodiments, N=273, and K=191. In some embodiments, the first predetermined threshold is 6.5 dB. In some embodiments, the raised-threshold majority-logic decoder comprises: an error corrector adapted to generate an error-corrected code block based on the input code block, comprising an orthogonal check module adapted to calculate results of a plurality of orthogonal check equations for the input code block with each of the symbols used as an orthogonal symbol, and an error correction module adapted to change the value of the respective symbol when a number of the respective results having a value of one exceeds a second predetermined threshold. In some embodiments, the raised-threshold majority-logic decoder further comprises: an error checker adapted to check the error-corrected code block for errors, comprising a parity check module adapted to calculate N−K parity check equations for the error-corrected code block, a decoding success module adapted to indicate that the decoding has succeeded when the all of the N−K check equations are satisfied, and a decoding failure module adapted to indicate that the decoding has failed when any of the N−K check equations are not satisfied. In some embodiments, the variable-threshold majority-logic decoder comprises: an error corrector adapted to generate an error-corrected code block based on the input code block, comprising a variable threshold module adapted to set a value of a variable threshold to a predetermined initial threshold value, an orthogonal check module adapted to calculate results of a plurality of orthogonal check equations for the input code block with each of the symbols used as an orthogonal symbol, and an error correction module adapted to change the value of the respective symbol when a number of the respective results having a value of one exceeds the value of the variable threshold. In some embodiments, the variable-threshold majority-logic decoder further comprises: an error checker adapted to check the error-corrected code block for errors, comprising a parity check module adapted to calculate N−K parity check equations for the error-corrected code block; a decoding success indication module adapted to indicate that the decoding has succeeded when the all of the N−K check equations are satisfied, and a decoding failure module adapted to indicate that the decoding has failed when any of the N−K check equations are not satisfied and the value of the variable threshold equals the value of a second predetermined threshold; wherein the variable threshold module is further adapted to decrease the value of the variable threshold when any of the N−K check equations are not satisfied and the value of the second predetermined threshold does not equal the value of the variable threshold; and wherein the error corrector is further adapted to generate a further error-corrected code block when the variable threshold module has decreased the value of the variable threshold.

In general, in one aspect, an embodiment features a method comprising: receiving a signal representing an input code block, wherein the input code block represents information encoded with a (N, K) difference-set cyclic code, wherein the input code block includes N symbols, and wherein the N symbols represent K bits of the information; estimating a signal-to-noise ratio of the signal; decoding the input code block according to a raised-threshold majority-logic decoding algorithm when the signal-to-noise ratio does not exceed a first predetermined threshold; and decoding the input code block according to a variable-threshold majority-logic decoding algorithm when the signal-to-noise ratio exceeds the first predetermined threshold.

Embodiments of the method can include one or more of the following features. In some embodiments, N=273, and K=191. In some embodiments, the first predetermined threshold is 6.5 dB. In some embodiments, decoding the input code block according to the raised-threshold majority-logic decoding algorithm comprises: generating an error-corrected code block based on the input code block, comprising, for each of the symbols of the code block, calculating results of a plurality of orthogonal check equations for the input code block with the respective symbol used as an orthogonal symbol, and changing the value of the respective symbol when a number of the results having a value of one exceeds a second predetermined threshold. In some embodiments, decoding the code block according to the raised-threshold majority-logic decoding algorithm further comprises: checking the error-corrected code block for errors, comprising calculating N−K check equations for the error-corrected code block; indicating that the decoding has succeeded when the all of the N−K check equations are satisfied, and indicating that the decoding has failed when any of the N−K check equations are not satisfied. In some embodiments, decoding the input code block according to the variable-threshold majority-logic decoding algorithm comprises: setting a value of a variable threshold to a predetermined initial threshold value; and generating an error-corrected code block based on the input code block, comprising, for each of the symbols of the code block, calculating results of a plurality of orthogonal check equations for the input code block with the respective symbol used as an orthogonal symbol, and changing the value of the respective symbol when a number of the results having a value of one exceeds the value of the variable threshold. In some embodiments, decoding the code block according to the variable-threshold majority-logic decoding algorithm further comprises: checking the error-corrected code block for errors, comprising calculating N−K check equations for the error-corrected code block; indicating that the decoding has succeeded when the all of the N−K check equations are satisfied, and indicating that the decoding has failed when any of the N−K check equations are not satisfied and the value of the variable threshold equals the value of a second predetermined threshold; decreasing the value of the variable threshold when any of the N−K check equations are not satisfied and the value of the second predetermined threshold does not equal the value of the variable threshold; and repeating the step of generating the error-corrected code block after decreasing the value of the variable threshold.

Some embodiments comprise a tangible computer-readable medium embodying instructions executable by a computer to perform a method comprising: receiving an input code block, wherein the input code block represents information encoded with a (N, K) difference-set cyclic code, wherein the input code block includes N symbols, and wherein the N symbols represent K bits of the information; receiving a signal-to-noise ratio of a signal representing the input code block; decoding the input code block according to a raised-threshold majority-logic decoding algorithm when the signal-to-noise ratio does not exceed a first predetermined threshold; and decoding the input code block according to a variable-threshold majority-logic decoding algorithm when the signal-to-noise ratio exceeds the first predetermined threshold. In some embodiments, N=273, and K=191. In some embodiments, the first predetermined threshold is 6.5 dB. In some embodiments, decoding the input code block according to the raised-threshold majority-logic decoding algorithm comprises: generating an error-corrected code block based on the input code block, comprising, for each of the symbols of the code block, calculating results of a plurality of orthogonal check equations for the input code block with the respective symbol used as an orthogonal symbol, and changing the value of the respective symbol when a number of the results having a value of one exceeds a second predetermined threshold. In some embodiments, decoding the code block according to the raised-threshold majority-logic decoding algorithm further comprises: checking the error-corrected code block for errors, comprising calculating N−K check equations for the error-corrected code block; indicating that the decoding has succeeded when the all of the N−K check equations are satisfied, and indicating that the decoding has failed when any of the N−K check equations are not satisfied. In some embodiments, decoding the input code block according to the variable-threshold majority-logic decoding algorithm comprises: setting a value of a variable threshold to a predetermined initial threshold value; and generating an error-corrected code block based on the input code block, comprising, for each of the symbols of the code block calculating results of a plurality of orthogonal check equations for the input code block with the respective symbol used as an orthogonal symbol, and changing the value of the respective symbol when a number of the results having a value of one exceeds the value of the variable threshold. In some embodiments, decoding the code block according to the variable-threshold majority-logic decoding algorithm further comprises: checking the error-corrected code block for errors, comprising calculating N−K check equations for the error-corrected code block; indicating that the decoding has succeeded when the all of the N−K check equations are satisfied, and indicating that the decoding has failed when any of the N−K check equations are not satisfied and the value of the variable threshold equals the value of a second predetermined threshold; decreasing the value of the variable threshold when any of the N−K check equations are not satisfied and the value of the second predetermined threshold does not equal the value of the variable threshold; and repeating the step of generating the error-corrected code block after decreasing the value of the variable threshold.

The details of one or more implementations are set forth in the accompanying drawings and the description below. Other features will be apparent from the description and drawings, and from the claims.

### DESCRIPTION OF DRAWINGS

FIG. 1 shows elements of a decoding receiver according to some embodiments.

FIG. 2 shows a process for the decoding receiver of FIG. 1 according to some embodiments.

FIG. 3 shows elements of the raised-threshold majority-logic decoder of FIG. 1 according to some embodiments.

FIG. 4 shows a process for the raised-threshold majority-logic decoder of FIG. 3 according to some embodiments.

FIG. 5 shows elements of the variable-threshold majority-logic decoder of FIG. 1 according to some embodiments.

FIGS. 6A and 6B show a process for the variable-threshold majority-logic decoder of FIG. 5 according to some embodiments.

The leading digit(s) of each reference numeral used in this specification indicates the number of the drawing in which the reference numeral first appears.

### DETAILED DESCRIPTION

Block codes that can correct several random errors generally don't have decoding algorithms that are easy to implement. However, if the codes bear some algebraic structures, a simple majority-logic algorithm can be adopted for decoding. One such class of majority-logic decodable codes is the difference-set cyclic code. A majority-logic decodable code is a code such that J orthogonal check equations with one orthogonal position can be established so that every symbol cᵢ of the codeword can be placed in the orthogonal position which appears in all J orthogonal check equations and all symbols other than cᵢ appear only once in the J orthogonal check equations. That is, the codeword can be circularly shifted to place a different symbol cᵢ in the orthogonal position, and the J orthogonal check equations are always satisfied. For the (273, 191) difference-set cyclic code, J=17.

Embodiments of the present disclosure provide elements of an SNR-based variable-threshold majority-logic decoder. According to various embodiments, a signal is received that represents an input code block, where the input code block represents information encoded with a (N, K) difference-set cyclic code. That is, the input code block includes N symbols that collectively represent K bits of the information. The signal can be any signal that employs difference-set cyclic codes. For example, the signal can be an ISDB-T (Integrated Services Digital Broadcasting-Terrestrial) signal.

According to various embodiments, a signal-to-noise ratio (SNR) of the signal is estimated. When the SNR of the signal does not exceed a predetermined SNR threshold, the input code block is decoded according to a raised-threshold majority-logic decoding algorithm in order to obtain a low wrong-indication rate at the cost of some decoding performance. When the SNR of the signal exceeds the SNR threshold, the input code block is decoded according to a variable-threshold majority-logic decoding algorithm in order to greatly reduce the wrong-indication rate, which is of crucial importance in some applications.

The decoding algorithms are described below for a (N, K) difference-set cyclic code where N=273 and K=191. However, these values of N and K are used by way of example, not limitation. That is, other embodiments employ other values for N and K.

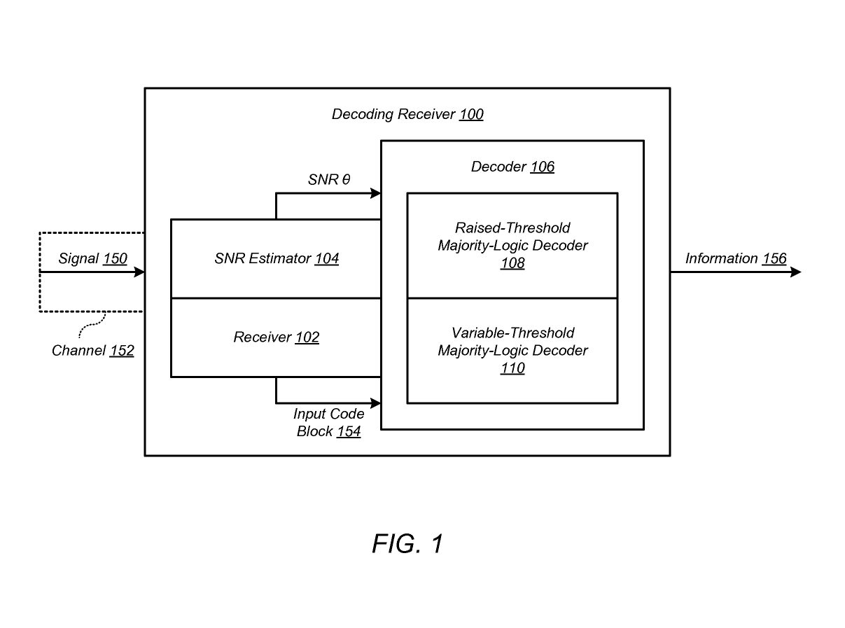

FIG. 1 shows elements of a decoding receiver 100 according to some embodiments. Although in the described embodiments, the elements of decoding receiver 100 are presented in one arrangement, other embodiments may feature other arrangements, as will be apparent based on the disclosure and teachings provided herein. For example, the elements of decoding receiver 100 can be implemented in hardware, software, or combinations thereof.

Referring to FIG. 1, decoding receiver 100 includes a receiver 102, an SNR estimator 104, and a decoder 106. Decoder 106 includes a raised-threshold majority-logic decoder 108 and a variable-threshold majority-logic decoder 110. Receiver 102 and SNR estimator 104 can be implemented according to conventional techniques. Decoder 106 is described in detail below.

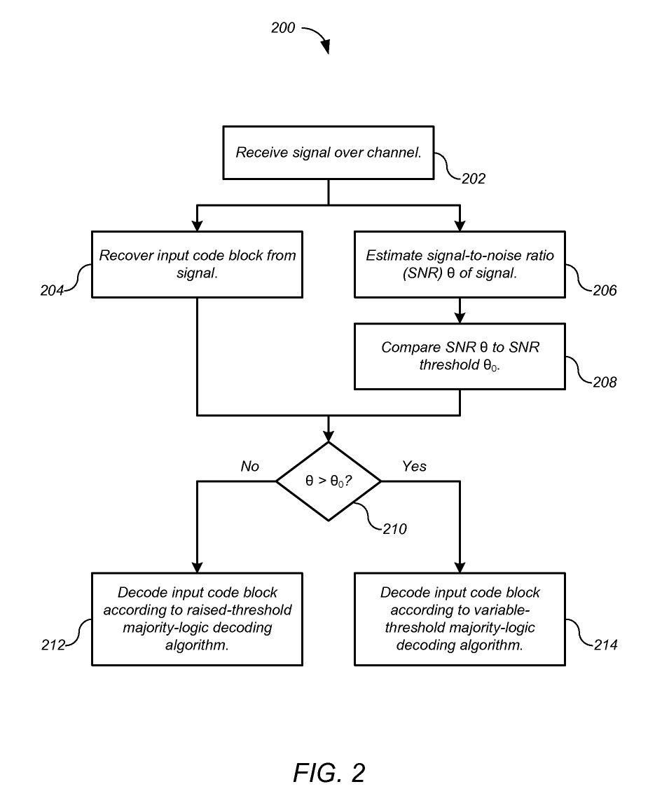

FIG. 2 shows a process 200 for decoding receiver 100 of FIG. 1 according to some embodiments. Although in the described embodiments, the elements of process 200 are presented in one arrangement, other embodiments may feature other arrangements, as will be apparent to one skilled in the relevant arts based on the disclosure and teachings provided herein. For example, in various embodiments, some or all of the steps of process 200 can be executed in a different order, concurrently, and the like.

Referring to FIGS. 1 and 2, receiver 102 receives a signal 150 over a channel 152 (step 202). Signal 150 represents an input code block 154. Input code block 154 represents information 156 encoded with a (N, K) difference-set cyclic code. That is, input code block 154 includes N symbols that together represent K bits of information 156. Channel 152 can be any sort of channel. For example, channel 152 can be wired, wireless, optical, a network channel or direct link, and so on. In one embodiment, channel 152 is a wireless channel, and signal 150 is an ISDB-T signal.

Receiver 102 recovers input code block 154 from signal 150, for example according to conventional demodulation techniques (step 204). Receiver 102 provides input code block 154 to decoder 106. Estimator 104 estimates a signal-to-noise ratio (SNR) θ of signal 150 (step 206). Any technique can be used to estimate SNR θ. Estimator 104 provides SNR θ to decoder 106.

Decoder 106 compares SNR θ to an SNR threshold θ₀ (step 208). In some embodiments, SNR threshold θ₀ is 6.5 dB. Of course, other values can be selected for SNR threshold θ₀. When SNR θ does not exceed SNR threshold θ₀ (θ≦θ₀) (step 210), raised-threshold majority-logic decoder 108 decodes input code block 154 according to a raised-threshold majority-logic decoding algorithm (step 212). But when SNR θ exceeds SNR threshold θ₀ (θ>θ₀), variable-threshold majority-logic decoder 110 decodes input code block 154 according to a variable-threshold majority-logic decoding algorithm (step 214). Example embodiments for raised-threshold majority-logic decoder 108 and variable-threshold majority-logic decoder 110 are described in detail below.

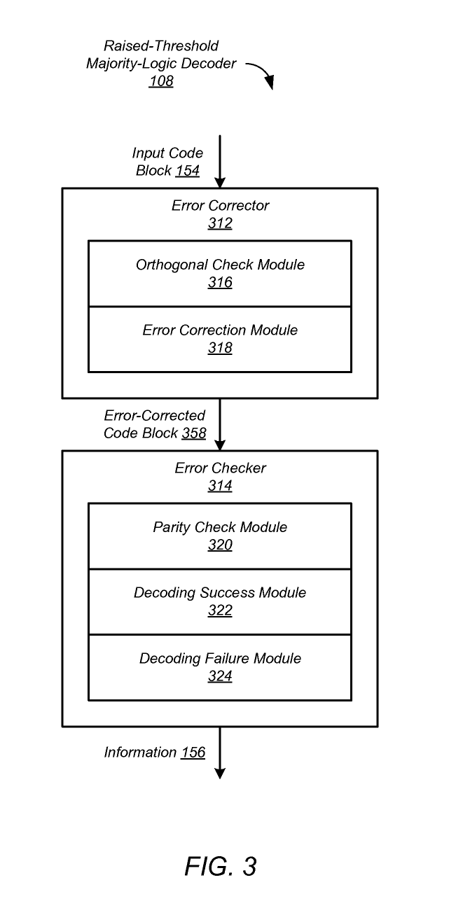

FIG. 3 shows elements of raised-threshold majority-logic decoder 108 of FIG. 1 according to some embodiments. Although in the described embodiments, the elements of raised-threshold majority-logic decoder 108 are presented in one arrangement, other embodiments may feature other arrangements, as will be apparent based on the disclosure and teachings provided herein. For example, the elements of raised-threshold majority-logic decoder 108 can be implemented in hardware, software, or combinations thereof.

Referring to FIG. 3, raised-threshold majority-logic decoder 108 includes an error corrector 312 and an error checker 314. Error corrector 312 includes an orthogonal check module 316 and an error correction module 318. Error checker 314 includes a parity check module 320, a decoding success module 322, and a decoding failure module 324.

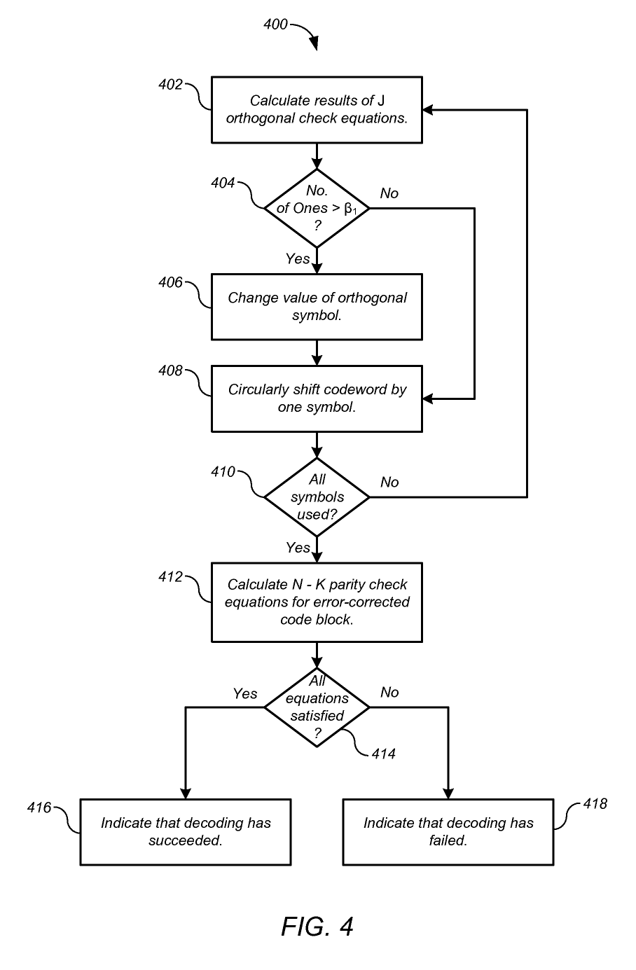

FIG. 4 shows a process 400 for raised-threshold majority-logic decoder 108 of FIG. 3 according to some embodiments. Although in the described embodiments, the elements of process 400 are presented in one arrangement, other embodiments may feature other arrangements, as will be apparent to one skilled in the relevant arts based on the disclosure and teachings provided herein. For example, in various embodiments, some or all of the steps of process 400 can be executed in a different order, concurrently, and the like.

Referring to FIGS. 3 and 4, error corrector 312 generates an error-corrected code block 358 based on input code block 154. In particular, orthogonal check module 316 calculates results of a plurality J of orthogonal check equations for input code block 154 with one of the symbols of input code block 154 used as an orthogonal symbol (step 402). For example, for the (273, 191) difference-set cyclic code, J=17. Continuing the example of the (273, 191) difference-set cyclic code, the codeword polynomial for input code block 154 is given by equation (1).

C(x)=c₀+c₁x+c₂x²+ . . . +c₂₇₂x²⁷² (1)

In the first iteration of step 402, the most-significant symbol c₂₇₂ of input code block 154 is used as the orthogonal symbol for calculating results of the J=17 orthogonal check equations. The orthogonal symbol appears in each of the J orthogonal check equations, while each of the remaining symbols of codeword C(x) appear in only one of the J orthogonal check equations. For example, for a difference-set codeword C(x) of length 7 having seven symbols (a1, a2, a3, a4, a5, a6, a7) and J=3, as a result of the mathematical properties of the difference set, the 3 orthogonal check equations can be as given by equations (2)-(4).

a1+a2+a3=0 (2)

a1+a4+a5=0 (3)

a1+a6+a7=0 (4)

For a cyclic difference-set codeword C(x), all of the cyclically-shifted codewords (a2, a3, a4, a5, a6, a7, a1), (a3, a4, a5, a6, a7, a1, a2), . . . (a7, a1, a2, a3, a4, a5, a6) also satisfy equations (2)-(4), as shown in equations (5)-(7).

a2+a3+a4=0 (5)

a2+a5+a6=0 (6)

a2+a7+a1=0 (7)

The result for each of the orthogonal check equations is either a one (“1”) or a zero (“0”). Error correction module 318 determines whether the number of results having a value of one (“1”) exceeds a predetermined threshold β₁ (step 404). In some embodiments, the value of threshold β₁ is selected to exceed the value of a reference threshold βₒᵣ where β₁>β₀ᵣ=9. When the number of results having a value of one (“1”) exceeds threshold β₁, error correction module 318 changes the value of the orthogonal symbol (step 406). That is, if the value of the orthogonal symbol is one (“1”), error correction module 318 changes the value of the orthogonal symbol to zero (“0”), and if the value of the orthogonal symbol is zero (“0”), error correction module 318 changes the value of the orthogonal symbol to one (“1”).

Error corrector 312 then circularly shifts codeword C(x) by one symbol (step 408). Error corrector 312 also circularly shifts codeword C(x) by one symbol (step 408) when the number of results having a value of one (“1”) does not exceed threshold β₁. As a result of the circular shift, a different symbol of codeword C(x) is the orthogonal symbol. If not all of the symbols have been used as the orthogonal symbol (step 410), then orthogonal check module 316 calculates results of the J orthogonal check equations for input code block 154 with the new orthogonal symbol (returning to step 402). This part of process 400 (that is, steps 402-410) repeats until all of the symbols have been used as the orthogonal symbol for calculating the J orthogonal check equations. The result is error-corrected code block 358.

When all of the symbols have been used as the orthogonal symbol for calculating the J orthogonal check equations, error checker 314 checks error-corrected code block 358 for errors. In particular, parity check module 320 calculates N−K parity check equations for error-corrected code block 358 (step 412). For example, for the (273, 191) difference-set cyclic code, N−K=273−191=82.

If all of the N−K check equations are satisfied (step 414), decoding success module 322 indicates that the decoding has succeeded (step 416), and process 400 ends. Otherwise, decoding failure module 324 indicates that the decoding has failed (step 418), and process 400 ends.

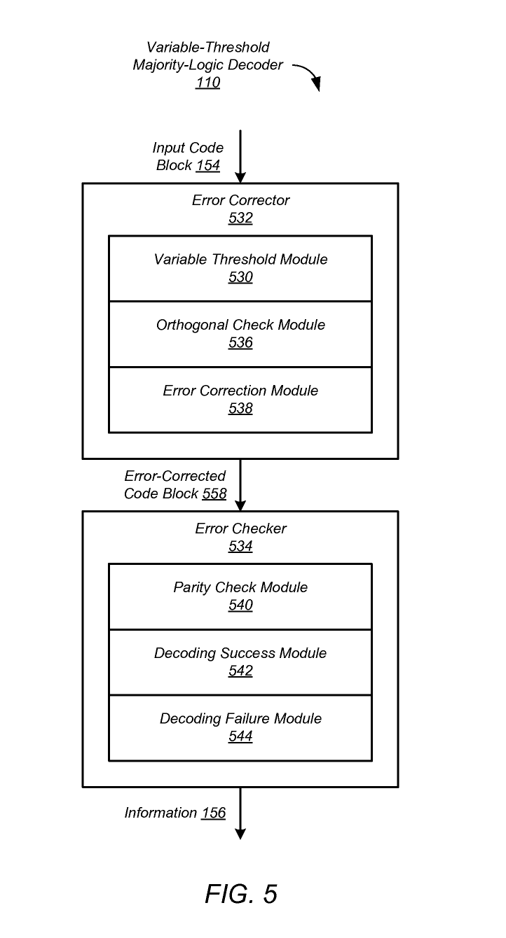

FIG. 5 shows elements of variable-threshold majority-logic decoder 110 of FIG. 1 according to some embodiments. Although in the described embodiments, the elements of variable-threshold majority-logic decoder 110 are presented in one arrangement, other embodiments may feature other arrangements, as will be apparent based on the disclosure and teachings provided herein. For example, the elements of variable-threshold majority-logic decoder 110 can be implemented in hardware, software, or combinations thereof.

Variable-threshold majority-logic decoder 110 includes an error corrector 532 and an error checker 534. Error corrector 532 includes a variable threshold module 530, an orthogonal check module 536 and an error correction module 538. Error checker 534 includes a parity check module 540, a decoding success module 542, and a decoding failure module 544.

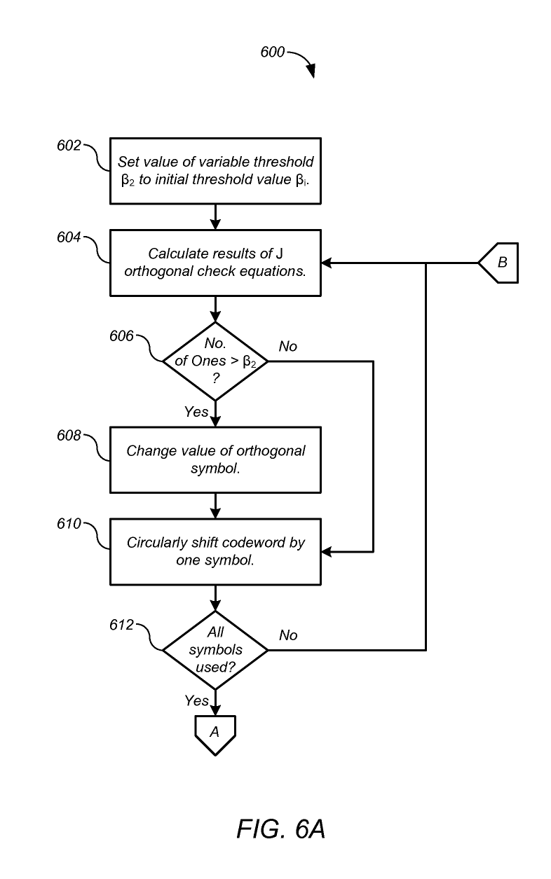

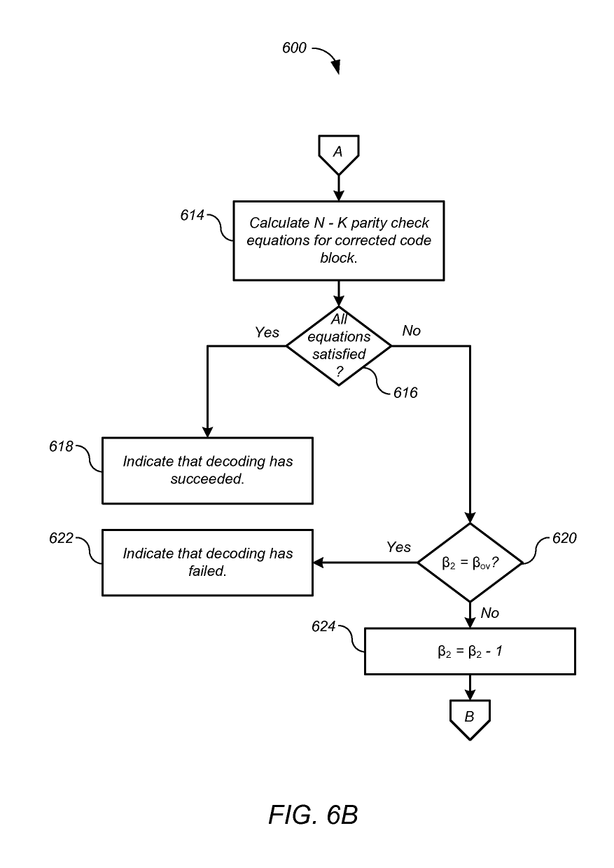

FIGS. 6A and 6B show a process 600 for variable-threshold majority-logic decoder 110 of FIG. 5 according to some embodiments. Although in the described embodiments, the elements of process 600 are presented in one arrangement, other embodiments may feature other arrangements, as will be apparent to one skilled in the relevant arts based on the disclosure and teachings provided herein. For example, in various embodiments, some or all of the steps of process 600 can be executed in a different order, concurrently, and the like.

Referring to FIGS. 5, 6A, and 6B, variable threshold module 530 sets a value of a variable threshold β₂ to a predetermined initial threshold value βᵢ (step 602). In some embodiments, βᵢ=9 . Then error corrector 532 generates an error-corrected code block 558 based on input code block 154. In particular, orthogonal check module 536 calculates results of a plurality J of orthogonal check equations for input code block 154 with one of the symbols of input code block 154 used as an orthogonal symbol (step 604) according to the technique described above for orthogonal check module 316.

Error correction module 538 determines whether the number of results having a value of one (“1”) exceeds threshold β₂ (step 606) according to the technique described above for error correction module 318. When the number of results having a value of one (“1”) exceeds threshold β₂, error correction module 538 changes the value of the orthogonal symbol (step 608). That is, if the value of the orthogonal symbol is one (“1”), error correction module 538 changes the value of the orthogonal symbol to zero (“0”), and if the value of the orthogonal symbol is zero (“0”), error correction module 538 changes the value of the orthogonal symbol to one (“1”).

Error corrector 532 then circularly shifts codeword C(x) by one symbol (step 610). Error corrector 532 also circularly shifts codeword C(x) by one symbol (step 610) when the number of results having a value of one (“1”) does not exceed threshold β₂. As a result of the circular shift, a different symbol of codeword C(x) is the orthogonal symbol. If not all of the symbols have been used as the orthogonal symbol (step 612), then orthogonal check module 536 calculates results of the J orthogonal check equations for input code block 154 with the new orthogonal symbol (returning to step 604). This part of process 600 (that is, steps 604-612) repeats until all of the symbols have been used as the orthogonal symbol for calculating the J orthogonal check equations. The result is a error-corrected code block 558.

When all of the symbols have been used as the orthogonal symbol for calculating the J orthogonal check equations, error checker 534 checks error-corrected code block 558 for errors. In particular, parity check module 540 calculates N−K parity check equations for error-corrected code block 558 (step 614) as described above for parity check module 320.

If all of the N−K check equations are satisfied (step 616), decoding success module 622 indicates that the decoding has succeeded (step 618), and process 600 ends. But if any of the N−K check equations are not satisfied (step 616), variable threshold module 530 determines whether the value of variable threshold β₂ is equal to a reference threshold value β_{0ν} (step 620). In some embodiments, β_{0ν}=9.

If the value of variable threshold β₂ is equal to reference threshold value β_{0σ} (step 620), then decoding failure module 618 indicates that the decoding has failed (step 622), and process 600 ends. But if the value of variable threshold β₂ is not equal to reference threshold value β_{0ν} (step 618), then variable threshold module 530 decreases the value of variable threshold β₂ (step 624). In some embodiments, variable threshold module 530 decreases the value of variable threshold β₂ by one (β₂=β₂−1). Error corrector 532 then generates a further error-corrected code block 558 (returning to step 604).

Simulations of embodiments of the present invention have been conducted using the (273, 191) difference-set cyclic code with binary phase-shift keying (BPSK) and an additive white Gaussian noise (AWGN) channel model with SNR threshold θ₀=6.5 dB, threshold β₁=11, and threshold β₂=12. The simulations show that the disclosed technique is about 0.5 dB superior to conventional majority-logic techniques at high SNR levels. However, at low SNR levels, the disclosed technique gives about 100-200 wrong indications of successfully decoded codewords in 10000 codewords, while conventional techniques give about 30-50 wrong indications in 10000 codewords. The disclosed techniques greatly reduce the wrong-indication rate (no wrong indication in 10000 words) at the cost of some performance loss, which is of minor importance at low SNR levels.

Embodiments of the disclosure can be implemented in digital electronic circuitry, or in computer hardware, firmware, software, or in combinations of them. Embodiments of the disclosure can be implemented in a computer program product tangibly embodied in a machine-readable storage device for execution by a programmable processor; and method steps of the disclosure can be performed by a programmable processor executing a program of instructions to perform functions of the disclosure by operating on input data and generating output. The disclosure can be implemented advantageously in one or more computer programs that are executable on a programmable system including at least one programmable processor coupled to receive data and instructions from, and to transmit data and instructions to, a data storage system, at least one input device, and at least one output device. Each computer program can be implemented in a high-level procedural or object-oriented programming language, or in assembly or machine language if desired; and in any case, the language can be a compiled or interpreted language. Suitable processors include, by way of example, both general and special purpose microprocessors. Generally, a processor will receive instructions and data from a read-only memory and/or a random access memory. Generally, a computer will include one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including by way of example semiconductor memory devices, such as EPROM, EEPROM, and flash memory devices; magnetic disks such as internal hard disks and removable disks; magneto-optical disks; and CD-ROM disks. Any of the foregoing can be supplemented by, or incorporated in, ASICs (application-specific integrated circuits).

A number of implementations of the disclosure have been described. Nevertheless, it will be understood that various modifications may be made without departing from the spirit and scope of the disclosure. Accordingly, other implementations are within the scope of the following claims.

What is claimed is:

1. An apparatus comprising:
a receiver adapted to receive a signal representing an input code block, wherein the input code block represents information encoded with a (N, K) difference-set cyclic code, wherein the input code block includes N symbols, and wherein the N symbols represent K bits of the information;
an estimator adapted to estimate a signal-to-noise ratio of the signal;
a raised-threshold majority-logic decoder adapted to decode the input code block according to a raised-threshold majority-logic decoding algorithm when the signal-to-noise ratio does not exceed a first predetermined threshold; and
a variable-threshold majority-logic decoder adapted to decode the input code block according to a variable-threshold majority-logic decoding algorithm when the signal-to-noise ratio exceeds the first predetermined threshold.

2. The apparatus of claim 1:
wherein N=273, and
wherein K=191.

3. The apparatus of claim 1:
wherein the first predetermined threshold is 6.5 dB.

4. The apparatus of claim 1, wherein the raised-threshold majority-logic decoder comprises:
an error corrector adapted to generate an error-corrected code block based on the input code block, comprising
an orthogonal check module adapted to calculate results of a plurality of orthogonal check equations for the input code block with each of the symbols used as an orthogonal symbol, and
an error correction module adapted to change the value of the respective symbol when a number of the respective results having a value of one exceeds a second predetermined threshold.

5. The apparatus of claim 4, wherein the raised-threshold majority-logic decoder further comprises:
an error checker adapted to check the error-corrected code block for errors, comprising
a parity check module adapted to calculate N−K parity check equations for the error-corrected code block,
a decoding success module adapted to indicate that the decoding has succeeded when the all of the N−K check equations are satisfied, and
a decoding failure module adapted to indicate that the decoding has failed when any of the N−K check equations are not satisfied.

6. The apparatus of claim 1, wherein the variable-threshold majority-logic decoder comprises:
an error corrector adapted to generate an error-corrected code block based on the input code block, comprising
a variable threshold module adapted to set a value of a variable threshold to a predetermined initial threshold value,
an orthogonal check module adapted to calculate results of a plurality of orthogonal check equations for the input code block with each of the symbols used as an orthogonal symbol, and
an error correction module adapted to change the value of the respective symbol when a number of the respective results having a value of one exceeds the value of the variable threshold.

7. The apparatus of claim 6, wherein the variable-threshold majority-logic decoder further comprises:
an error checker adapted to check the error-corrected code block for errors, comprising
a parity check module adapted to calculate N−K parity check equations for the error-corrected code block;
a decoding success indication module adapted to indicate that the decoding has succeeded when the all of the N−K check equations are satisfied, and
a decoding failure module adapted to indicate that the decoding has failed when any of the N−K check equations are not satisfied and the value of the variable threshold equals the value of a second predetermined threshold;
wherein the variable threshold module is further adapted to decrease the value of the variable threshold when any of the N−K check equations are not satisfied and the value of the second predetermined threshold does not equal the value of the variable threshold; and
wherein the error corrector is further adapted to generate a further error-corrected code block when the variable threshold module has decreased the value of the variable threshold.

8. A method comprising:
receiving a signal representing an input code block, wherein the input code block represents information encoded with a (N, K) difference-set cyclic code, wherein the input code block includes N symbols, and wherein the N symbols represent K bits of the information;
estimating a signal-to-noise ratio of the signal;
decoding the input code block according to a raised-threshold majority-logic decoding algorithm when the signal-to-noise ratio does not exceed a first predetermined threshold; and
decoding the input code block according to a variable-threshold majority-logic decoding algorithm when the signal-to-noise ratio exceeds the first predetermined threshold.

9. The method of claim 8:
wherein N=273, and
wherein K=191.

10. The method of claim 8:
wherein the first predetermined threshold is 6.5 dB.

11. The method of claim 8, wherein decoding the input code block according to the raised-threshold majority-logic decoding algorithm comprises:
generating an error-corrected code block based on the input code block, comprising, for each of the symbols of the code block
calculating results of a plurality of orthogonal check equations for the input code block with the respective symbol used as an orthogonal symbol, and
changing the value of the respective symbol when a number of the results having a value of one exceeds a second predetermined threshold.

12. The method of claim 11, wherein decoding the code block according to the raised-threshold majority-logic decoding algorithm further comprises:
checking the error-corrected code block for errors, comprising
calculating N−K check equations for the error-corrected code block;
indicating that the decoding has succeeded when the all of the N−K check equations are satisfied, and
indicating that the decoding has failed when any of the N−K check equations are not satisfied.

13. The method of claim 8, wherein decoding the input code block according to the variable-threshold majority-logic decoding algorithm comprises:
setting a value of a variable threshold to a predetermined initial threshold value; and
generating an error-corrected code block based on the input code block, comprising, for each of the symbols of the code block
calculating results of a plurality of orthogonal check equations for the input code block with the respective symbol used as an orthogonal symbol, and
changing the value of the respective symbol when a number of the results having a value of one exceeds the value of the variable threshold.

14. The method of claim 13, wherein decoding the code block according to the variable-threshold majority-logic decoding algorithm further comprises:
checking the error-corrected code block for errors, comprising
calculating N−K check equations for the error-corrected code block;
indicating that the decoding has succeeded when the all of the N−K check equations are satisfied, and
indicating that the decoding has failed when any of the N−K check equations are not satisfied and the value of the variable threshold equals the value of a second predetermined threshold;
decreasing the value of the variable threshold when any of the N−K check equations are not satisfied and the value of the second predetermined threshold does not equal the value of the variable threshold; and
repeating the step of generating the error-corrected code block after decreasing the value of the variable threshold.

15. A tangible computer-readable medium embodying instructions executable by a computer to perform a method comprising:
receiving an input code block, wherein the input code block represents information encoded with a (N, K) difference-set cyclic code, wherein the input code block includes N symbols, and wherein the N symbols represent K bits of the information;
receiving a signal-to-noise ratio of a signal representing the input code block;
decoding the input code block according to a raised-threshold majority-logic decoding algorithm when the signal-to-noise ratio does not exceed a first predetermined threshold; and
decoding the input code block according to a variable-threshold majority-logic decoding algorithm when the signal-to-noise ratio exceeds the first predetermined threshold.

16. The tangible computer-readable medium of claim 15:
wherein N=273, and
wherein K=191.

17. The tangible computer-readable medium of claim 15:
wherein the first predetermined threshold is 6.5 dB.

18. The tangible computer-readable medium of claim 15, wherein decoding the input code block according to the raised-threshold majority-logic decoding algorithm comprises:
generating an error-corrected code block based on the input code block, comprising, for each of the symbols of the code block
calculating results of a plurality of orthogonal check equations for the input code block with the respective symbol used as an orthogonal symbol, and
changing the value of the respective symbol when a number of the results having a value of one exceeds a second predetermined threshold.

19. The tangible computer-readable medium of claim 18, wherein decoding the code block according to the raised-threshold majority-logic decoding algorithm further comprises:
checking the error-corrected code block for errors, comprising
calculating N−K check equations for the error-corrected code block;
indicating that the decoding has succeeded when the all of the N−K check equations are satisfied, and
indicating that the decoding has failed when any of the N−K check equations are not satisfied.

20. The tangible computer-readable medium of claim 15, wherein decoding the input code block according to the variable-threshold majority-logic decoding algorithm comprises:
setting a value of a variable threshold to a predetermined initial threshold value; and
generating an error-corrected code block based on the input code block, comprising, for each of the symbols of the code block
calculating results of a plurality of orthogonal check equations for the input code block with the respective symbol used as an orthogonal symbol, and
changing the value of the respective symbol when a number of the results having a value of one exceeds the value of the variable threshold.

21. The tangible computer-readable medium of claim 20, wherein decoding the code block according to the variable-threshold majority-logic decoding algorithm further comprises:
checking the error-corrected code block for errors, comprising
calculating N−K check equations for the error-corrected code block;
indicating that the decoding has succeeded when the all of the N−K check equations are satisfied, and
indicating that the decoding has failed when any of the N−K check equations are not satisfied and the value of the variable threshold equals the value of a second predetermined threshold;
decreasing the value of the variable threshold when any of the N−K check equations are not satisfied and the value of the second predetermined threshold does not equal the value of the variable threshold; and
repeating the step of generating the error-corrected code block after decreasing the value of the variable threshold.
